(19) United States
(12) Patent Application Publication
(10) Pub. No.: US 2005/0133929 A1
(43) Pub. Date: Jun. 23, 2005

(54) Flexible package with rigid substrate segments for high density integrated circuit systems

(76) Inventor: Gregory E. Howard, Dallas, TX (US)

Correspondence Address: TEXAS INSTRUMENTS INCORPORATED, P O BOX 655474, M/S 3999, DALLAS, TX, 75265, US

(21) Appl. No.: 10/739,418

(22) Filed: Dec. 18, 2003

(51) Int. Cl. H01L 23/48

(52) U.S. Cl. 257/774; 257/786

(57) ABSTRACT

A reliable, flexible package for high density, high performance, high I/O semiconductor devices including spaced-apart relatively rigid substrate segments mounted on a flexible interconnection layer to mitigate thermally induced stresses. The flexible interconnection layer may further include an integrated ribbon cable connector to provide a secondary system contact.

### FIELD OF THE INVENTION

This invention relates to packaging of integrated circuit devices and in particular to a stress mitigating package assembly.

### BACKGROUND OF THE INVENTION

Integrated circuits, often referred to as “semiconductor chips”, include numerous electronic components. The increase in device complexity, the decrease in feature size, and increase in the number of input/output (I/O) terminals has increased the complexity and difficulty of forming reliable interconnections between the chips and external devices.

Typically, each chip is mounted on a substrate which mechanically supports the chip and provides a means for electrical interconnection between the chip and a second level of interconnection, such as the circuitry on a printed wiring board. An increasingly popular semiconductor package, illustrated in FIG. 1a, is a ball grid array (BGA) 10 wherein chip 11 is electrically connected to conductive pads 12 on the first surface of substrate 15 and in turn to solder balls 14 on the second surface which provide external contacts to a second level of interconnection 13. As the chip size and number of I/O's has increased so has the package size, and as a result high levels of stress are placed on the rigid contact interfaces 141 and on the package itself due to thermal mismatches between the packaged device 10 and the printed wiring board (PWB) 13 to which the device is connected.

In an alternate packaging technology, multiple chips 18 are arrayed and interconnected on a single substrate 17 to form a multi-chip module 16, as illustrated in FIG. 1b. This technology has advantages for some electronic device applications in that it requires less board space than multiple individual packages and in decreasing the signal path between chips as a result of shorter and controlled interconnection design and fabrication. In a multi-chip module a plurality of chips 18 are connected to a substrate 17 which includes the power and signal lines 19 needed to supply power, and to interconnect the chips to each other and to external devices.

Interconnection is frequently made on thin film substrates of materials such as polyimide or other low dielectric polymers with photopatterned conductors, and in most cases the flexible film is supported by a more rigid substrate material. As a result of the large size of the substrate, the external contacts experience high levels of mechanical stresses from thermal expansion mismatches between the substrate and next level of interconnection. The external contacts are typically short solder balls which are subject to cracks and damage from stress and fatigue. Stresses on the contacts and fragile contact interfaces often result in significant reliability issues, such as open or intermittent contacts. The thermal mismatches occur both as a result of the reflow attachment process and the device operation.

Reduction or elimination of the damaging thermal stresses on solder joints and their interfaces would be advantageous for the industry both now and in the future for these large area and high I/O devices.

### SUMMARY OF THE INVENTION

In accordance with an embodiment of the invention, a semiconductor device is provided, including one or more semiconductor chips, a plurality of spaced-apart, relatively rigid substrate segments mounted on a flexible interconnection layer, and a plurality of external contacts. External contacts, including solder balls, for example, provide electrical connection to the next level of system interconnection and are positioned under each of the substrate segments. The flexible interconnection layer includes conductive traces that provide connection between chips and/or substrate segments, and connection to external contacts. In addition, it allows mechanical flexibility for the device. The ability of the interconnection layer to flex between more rigid segments mitigates damaging stresses resulting from thermal mismatches between the device and the second level of interconnections.

In other embodiments, the flexible interconnection layer includes an integrated flexible cable to provide for connection to a portion of the system remote from that portion having solder ball contacts. This dual interconnection layer may eliminate the need and expense for additional layers in the system PCB.

The flexible interconnection layer can be designed for low inductance interconnections by matching trace widths, trace to ground plane spacing, and/or ground and power port locations. Impedance matching of the traces on the interconnection layer can be controlled to reduce reflections and allow higher speed operations.

The device may be assembled by connection of the flexible interconnection layer directly to the chip terminals. Conductors in the flex layer are routed to the substrate segments which have external contacts under each rigid segment (flex on top embodiment).

Alternately, the chip(s) may be connected directly to conductive vias in the substrate segment(s) and the interconnection layer used to route between the various substrate segments and to external solder contacts (flex on bottom embodiment).

Connection between the chip and flex or substrate segments is preferably by flip chip contacts, but wire bonding, or other chip contact methods are applicable. Plated vias are the preferred conductors through the rigid substrate segments.

In one embodiment of the invention a high I/O, large area semiconductor chip is attached to a substrate segment which is surrounded by multiple substrate segments. The substrate segments are connected to the centrally located chip substrate by the flexible interconnection layer, which in turn is connected to external contacts. Use of multiple smaller substrate segments to support the solder balls and interconnection by a flexible layer lessens stress on the contacts.

The flexible interconnection layer is comprised of a polymeric material having a low dielectric constant and low thermal expansion coefficient, such as a member of the polyimide family. One or more levels of interconnection traces in the flexible layer are comprised of copper or a copper alloy having external surfaces protected from the environment by a thin film of a more inert material. Conductors extending through the flex layer are used to interconnect selected traces.

The relatively rigid substrate segments are composed of a laminate or polymeric material such as BT, FR-4, or FR-5 resin having a tensile modulus of greater than 50 GPa and metallic traces and/or vias having low resistivity.

In specific embodiments, a structure for covering and protecting the active chip(s) in the device is provided, but the structure does not cover the flexible ribbon connector.

The stress mitigating assembly of the current invention improves device reliability, performance and is cost effective both to the fabricator and to the user. A number of device and assembly options are provided.

### BRIEF DESCRIPTION OF THE DRAWINGS

FIG. 1a is a cross sectional view of a Ball Grid Array (BGA) Package of known art.

FIG. 1b is top view of a multi-chip module of existing technology.

FIG. 2a is a cross sectional view of one embodiment of the invention, comprising a single chip with multiple rigid substrate segments and the flex interconnection on the bottom.

FIG. 2b is a top view of the single chip device with rigid substrate segments and a flexible layer.

FIG. 3a is a cross sectional view of the single chip device and rigid substrate segments with flex interconnection on top.

FIG. 3b is a cross sectional view of the device of FIG. 3a with a cover protecting the chip.

FIG. 4a is a cross sectional view of a multi-chip embodiment with multiple rigid substrate segments and the flex interconnection layer on the top.

FIG. 4b is a cross sectional view of a multi-chip embodiment with multiple rigid substrate segments in a “flex-on-bottom” configuration.

FIG. 5a is a top view of the integrated flexible cable.

FIG. 5b shows a cross section of the semiconductor device of FIG. 4b on a flex interconnection with ribbon cable connections and solder ball contacts.

### DETAILED DESCRIPTION OF THE DRAWINGS

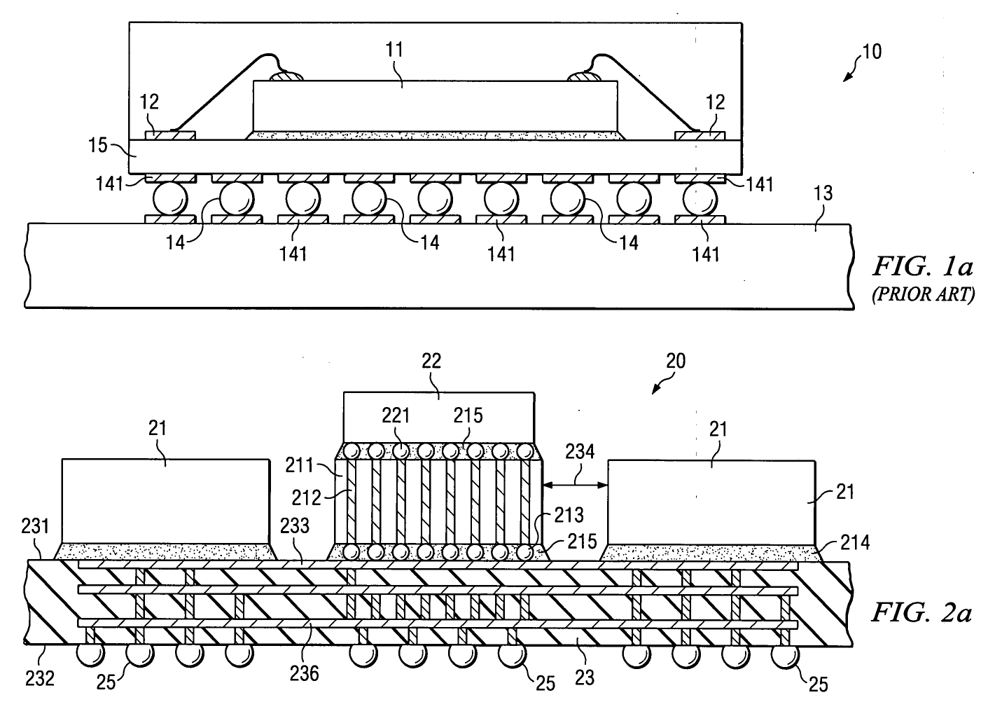

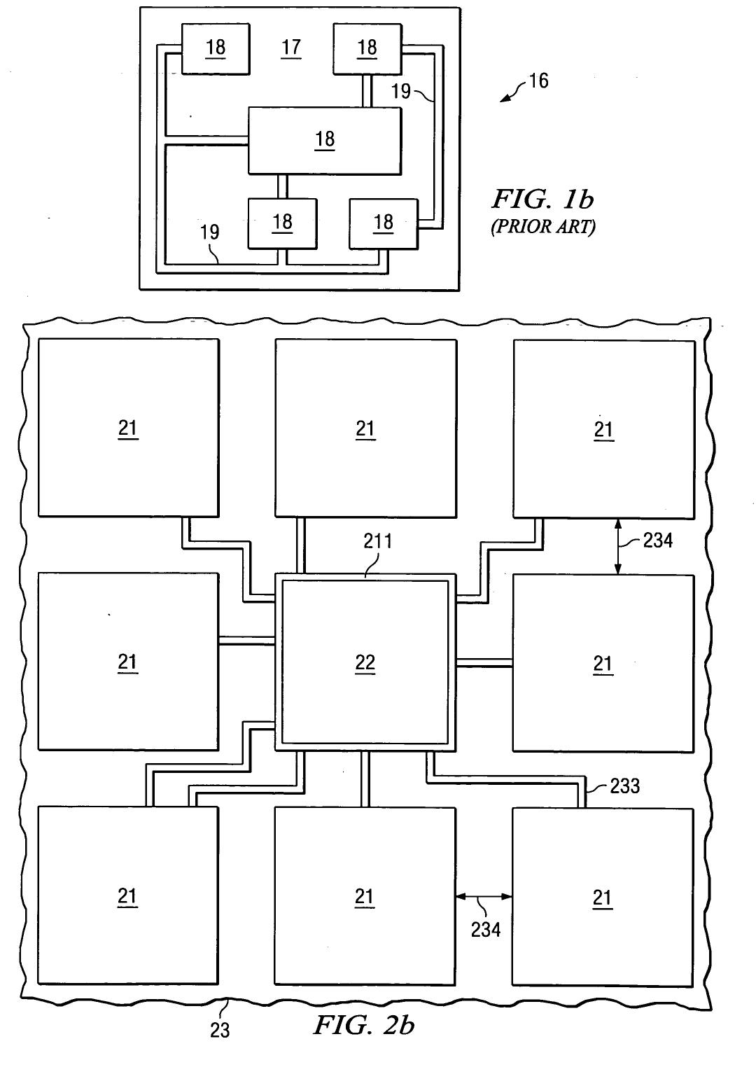

FIG. 2a is a cross sectional view of one embodiment of the invention, including a semiconductor device 20 having multiple rigid substrate segments 21 and 211 attached to a flexible interconnection layer 23. The ability of interconnection layer 23 to flex or to expand and contract between relatively small substrate segments 21 and 211 provides a relief mechanism to minimize thermally induced stresses on external contacts, preferably solder balls 25. In this embodiment, the terminals of semiconductor chip 22, having a large area and/or a high number of I/Os (input/output contacts), are connected to a substrate segment 211, preferably by flip chip bumps 221. The chip supporting substrate segment 211 includes a plurality of conductive vias 212 through which the chip bumps 221 are connected with patterned conductive traces 233 on flexible interconnection layer 23.

Substrate segment 211 and chip 22 are centrally located in device 20 and are surrounded by a plurality of substrate segments 21. Each of the substrate segments 21,211 is positioned atop flexible layer 23 which provides mechanical support for the external contacts 25.

Connectors 213 between the chip substrate segment 211 and conductive traces 233 on the first surface 231 of flexible interconnection layer 23 comprise solder, anisotropic adhesive or metal coated spheres embedded in an adhesive. Traces 233 on first surface 231 are routed to other selected conductive layers 236 or directly through the flexible layer 23 to external contacts, preferably solder balls 25 on the second surface 232.

This embodiment wherein a plurality of rigid substrate segments 21,211 are attached to the first surface 231 of a flexible interconnection layer, and to external solder ball contacts 25 to the second surface 232 of the interconnection layer is referred to as the “flex on bottom” option. Substrate segments 21 which have no chips attached will be referred to as inactive and those segments 211 with attached chips are active substrates. The inactive segments may include copper layers for thermal dissipation.

The rigid substrate segments 21,211 comprised of a dielectric material, such as BT, FR-4, or FR-5 resins, having a tensile modulus equal to or greater than 50 GPa provide mechanical support for the solder ball contacts and for the assembled device. Active substrates 211 for chip attachment having conductive vias 212 may include routing traces and pads for contact with the flexible interconnection layer 23. Inactive substrate segments are mechanically adhered to the flex layer by an adhesive 214. Each substrate segment has a thickness of about 0.65 mm to 2.5 mm and an area larger than the chip.

In this embodiment, contact between terminals on the chip 22 and conductive vias 212 in the active substrate segment 211 is by flip chip bumps 221, preferably comprising solder. Each conductive via 212, in turn, is connected to a conductive trace 233 on the interconnection layer 23 preferably by solder or an anisotropic conductive adhesive 213. Both the chip to via contacts 221 and/or via to flexible layer contacts 213 may be protected from mechanical stresses by an underfill polymer 215.

Flexible interconnection layer 23 comprises a polymeric material having a low dielectric constant, low thermal expansion, and a tensile modulus preferably in the range of 2 to 10 GPa, including, for example, a member of the polyimide family, and one or more levels of conductive traces 233. The flexible layer is preferably thinner than the substrate and is approximately 5 to 50 times lower in modulus.

Conductors in the flexible layer connect selected traces 233, 236 with contacts on second surface 232. Thickness of flexible layer 23 is from 25 to 250 microns, and is usually a function of the number of conductive trace levels 233,236 within the interconnection layer. Conductive traces in and on the interconnection layer comprise copper with a thin layer of a solder compatible material which provides protection from environmental exposure. The conductive traces include not only signal lines, but may also include power and ground planes.

A top view of the semiconductor device having rigid substrate segments and a flexible interconnection layer is illustrated in FIG. 2b. Chip 22 positioned atop the centrally located substrate segment 211 is surrounded by a plurality of inactive substrate segments 21. Conductive traces 233 are supported by the flexible interconnection layer 23. Open areas 234 between the more rigid substrate segments 21,211 are free to move with thermal and mechanical changes in the system without imparting significant stress on contacts 25 on the opposite surface of the device. The width of each open space 234 is preferably about one-fourth the thickness of a substrate segment 21, 211. Areas 234 between substrate segments provide latitude for the flex layer to absorb thermal and mechanical stresses, precludes contact between segment edges, and provides support for the package.

The relatively small, multiple substrates 21,211 interconnected by way of the flexible layer 23 to the solder balls 25 avoids excessively high stresses on the more fragile solder ball interfaces when the device 20 is attached to a PCB (printed circuit board) or other next level of interconnection (not shown). Printed circuit boards (PCB) or other system level interconnections typically are thicker than the device level substrates and are fabricated from a relatively high thermal expansion composite material which imparts stresses on the contacts of semiconductor devices as the system PCB expands and contracts. Stresses on short, rigid solder ball contacts can result in opens or intermittent failures, if the stresses are not relieved. The current invention having a flexible layer between smaller more rigid substrates provides a means for stress relief.

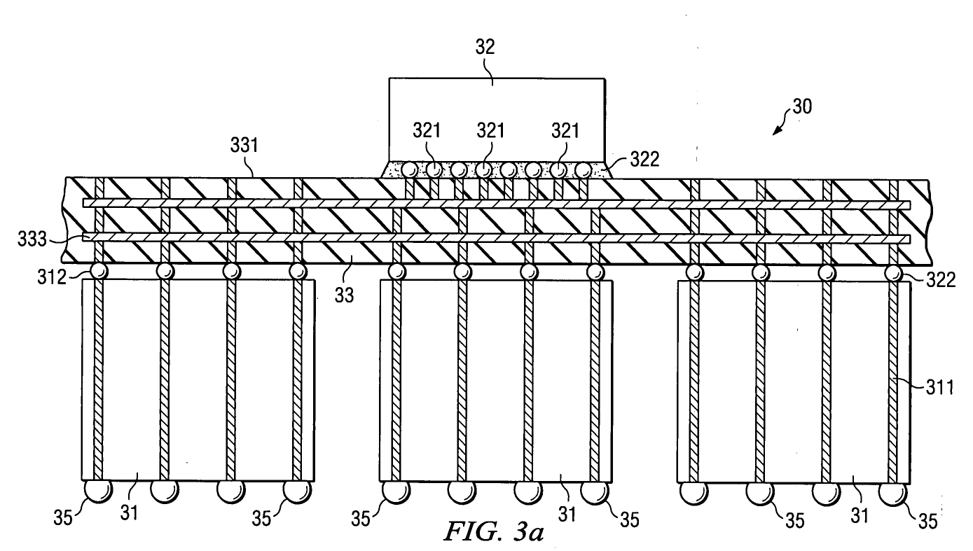

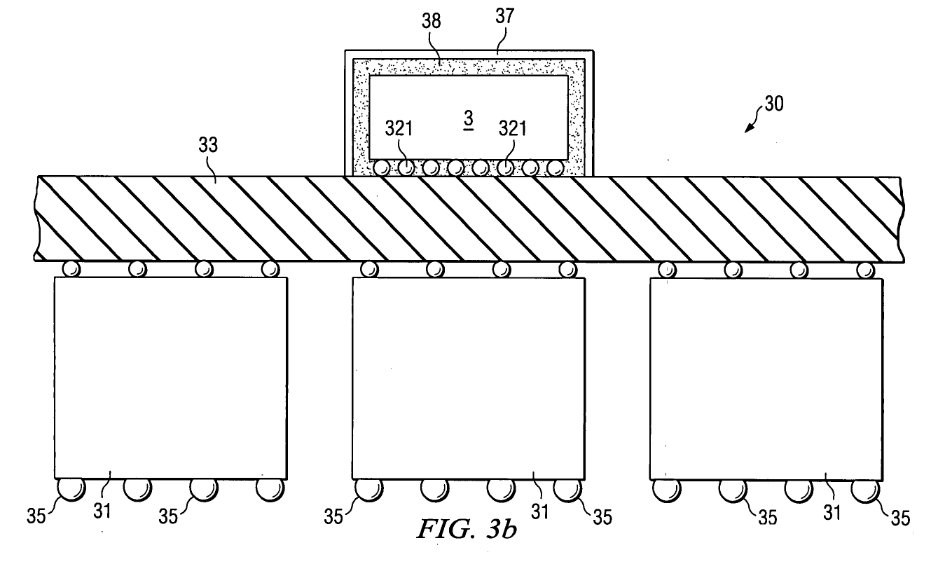

In a second embodiment of the invention as illustrated in FIG. 3a, device 30 includes semiconductor chip 32 connected to the first surface 331 of flexible interconnection layer 33 and a plurality of substrate segments 31 connected to the second surface of the interconnection layer. Conductive vias 311 through substrate segments 31 provide connection between external solder ball contacts 35 and interconnection layer 33. This second embodiment will be referred to as the “flex-on-top” option.

Materials of construction for the “flex-on-top” are similar to those in the “flex-on-bottom” option. Chip 32 connections to the first surface 311 of the interconnection layer 31 are preferably flip chip bumps 321, but alternate chip contact techniques such as wire bonding may be used. The flexible interconnection layer 33 comprises a low dielectric polymer with conductive traces 333 providing signal, power and ground connections to substrate segments 31.

Contacts 312 between the flexible layer 33 and relatively rigid substrate segments 31 may include solder, anisotropic adhesives, or metal coated balls embedded in an adhesive. An underfill material, typically comprising a polymer, may fill the space between contacts 321 and/or 312 to flex layer 33.

As depicted in FIG. 3b, an embodiment is provided wherein chip 3 and bumps 321 or other interconnections are protected by a preformed cap 37 which may be filled with a polymeric material 38. The cap 37 provides mechanical protection for chip 3 and precludes electrical contact with the back side of the chip. A cap covering the chip is applicable to either the “flex-on-top” or “flex-on-bottom” embodiment.

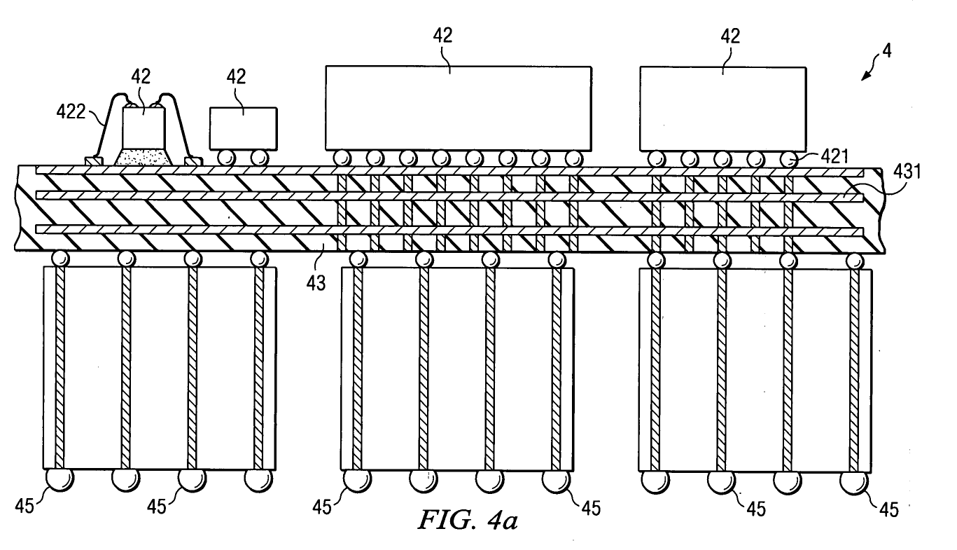

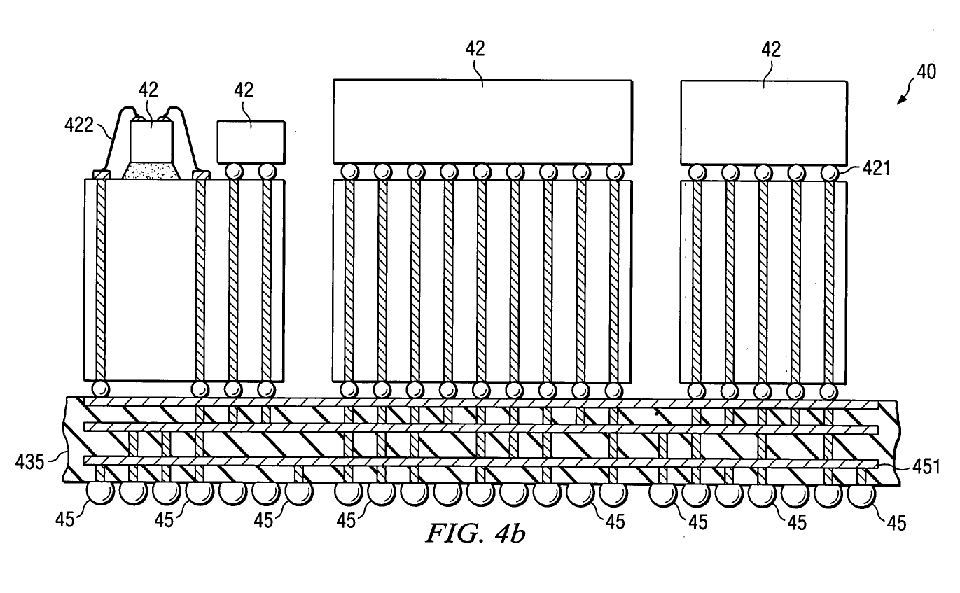

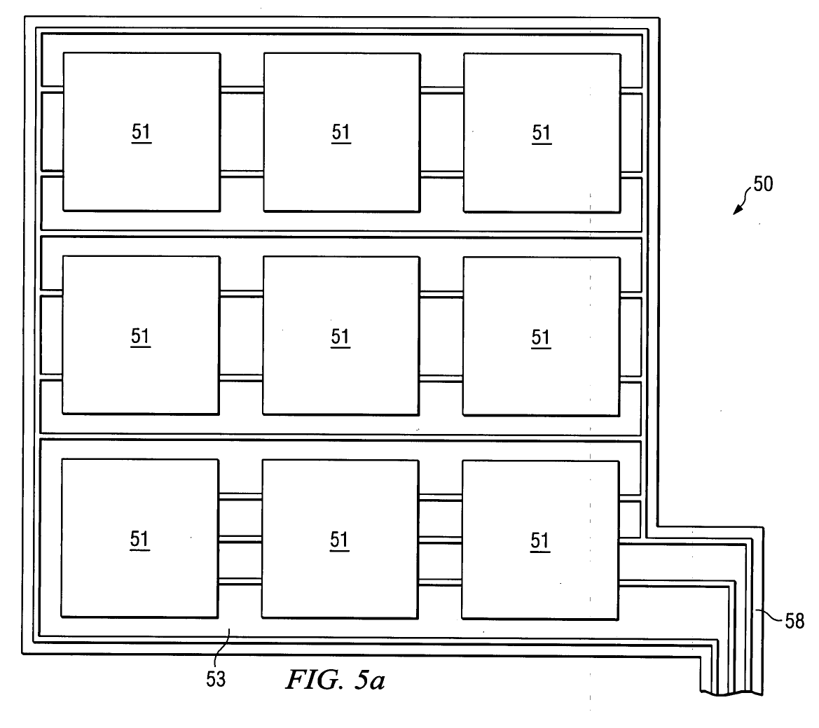

Semiconductor devices 20 and 30 depicted in FIGS. 2 and 3 demonstrate single chip embodiments of the invention; however, the assemblage including a multi-segment substrate and flexible interconnection layer is readily adapted to a multi-chip device. FIG. 4a illustrates a “flex-on-top” multi-chip module 4, and device 40 in FIG. 4b is a “flex-on-bottom” embodiment. A circuit having a combination of integrated circuit chips, discrete chips, resistors and/or capacitors may be included in module 4 or module 40, and may be attached by flip chip bump bonding 421, wire bonding 422, or other connection processes.

The flexible interconnection layers 43 and 435 are well suited to a reliable, high performance multi-chip module embodiment. Conductive planes and traces 431 and 451 comprising patterned thin film metallization within and on the surfaces of flexible dielectric interconnection layers 43 and 435 are readily customized to enhance device performance. For high speed devices having enhanced performance obtained by controlling the impedance of signal paths, the trace widths can be matched, the trace to ground spacing can be controlled, and the ground and power port locations selected in the interconnection layer, thereby providing controlled impedance and reduced reflections.

The multiple substrate segments of the current invention are superior to large rigid substrates, typical of existing multi-chip modules. The flexible interconnection layer not only allows movement between the segments to avoid high levels of stress on the contacts, but also provides a customized structure for high performance interconnection.

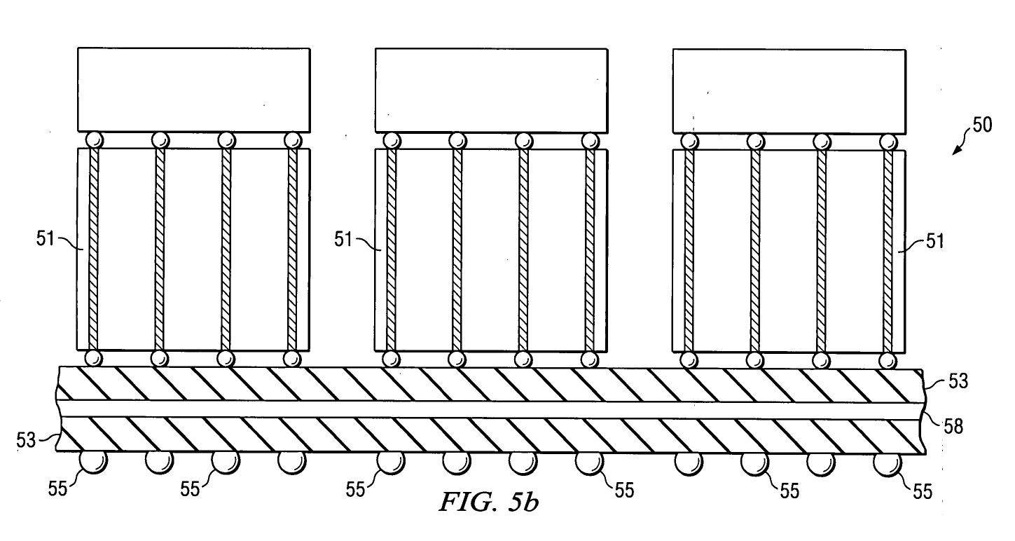

FIGS. 5a and 5b illustrate yet another embodiment of the invention, including flexible semiconductor device 50 having multiple substrate segments 51 and a flexible interconnection layer 53. External contacts include both solder balls 55 on the second surface of the interconnection layer and an integrated flexible cable 58 for plug-in connection. Cable 58 can be used to plug either I/Os for signal, power or ground into a connector on one portion of a system PCB while the solder balls 55 provide contacts to a second portion of the system. The flexible cable connection coupled with the solder ball contacts to different portions of the system significantly reduces the number of costly layers in a system PCB. Further, flexibility and extension of the ribbon type cable allows latitude in the location of connections, such as a wrap around or to a second PCB.

Interconnection layer 53 having connections for both solder balls 55 under the device and a ribbon cable connector 58 are applicable to single and multi-chip embodiments, as well as “flex-on-top” or “flex-on-bottom” embodiments. Similarly, the device having only one type of external contacts is applicable to any aforementioned embodiments.

It will be recognized that a semiconductor device including multiple substrate segments interconnected by a flexible layer is amenable to many modifications which will become apparent to those skilled in the art. Therefore, it is intended that the appended claims be interpreted as broadly as possible.

1. A reliable, high density, high performance semiconductor device comprising:
a) a plurality of spaced-apart substrate segments;
b) an integrated circuit chip mounted on one of said segments; and
c) a flexible interconnection layer supporting said substrate segments.

2- The device of claim 1 wherein said device further includes
a plurality of conductive vias extending through one of said substrate segments connected to the terminals of said chip;
said vias also electrically and mechanically connected to pads and/or traces on a first surface of said interconnection layer.

3- The device of claim 2 wherein said substrate segment having an integrated circuit chip mounted thereon is surrounded by a plurality of substrate segments on said interconnection layer, each substrate segment positioned over a plurality of external contacts on the opposite surface of said interconnection layer.

4- The assembled device of claim 1 wherein said flexible interconnection layer comprises a low dielectric polymeric film having a tensile modulus in the range of 2 to 10 GPa, and one or more levels of conductive traces connecting selected layers.

5- The assembled device of claim 1 wherein said substrate segments comprise a BT resin from 0.65 mm to 2.5 mm thick, a tensile modulus of greater than 50 GPa, and each of said segments is larger in area than said integrated circuit chip.

6- The assembled device of claim 1 wherein each of said substrate segments comprises an FR-4 composite having a thickness of 0.65 mm to 2.5 mm, a tensile modulus of greater than 50 GPa, and each of said segments is larger in area than said integrated circuit chip.

7- The assembled device of claim 1 wherein said integrated circuit chip contacts comprise flip chip bumps.

8- The assembled device of claim 1 wherein said external contacts comprise solder balls.

9- The assembled device of claim 1 wherein said connections between said substrate segments and said interconnection layer are comprised of solder.

10- The assembled device of claim 1 wherein said connections between said substrate segments and said interconnection layer are comprised of an anisotropic conductive adhesive.

11- The assembled device of claim 1 further including a preformed cap covering said integrated circuit chip and its interconnections.

12- A reliable, high density, high performance multi-chip module comprising:
a) a plurality of substrate segments mounted on one surface of a flexible interconnection layer;
b) a plurality of electronic components including integrated circuit chips, discrete chips, resistors, and/or capacitors mounted on the opposite surface of said interconnection layer;
c) said flexible interconnection layer including means for connecting said substrate segments, and
d) a plurality of external contacts on said substrate segments.

13- The module of claim 12 wherein said electronic components are interconnected to each other and to said external contacts by a plurality of conductive vias extending through said substrate segments, and conductors on and in said flexible interconnection layer.

14- The module of claim 13 wherein said substrate segments are positioned atop a plurality of external solder ball contacts on the second surface of said interconnection layer.

15- The multi-chip module claim 12 wherein said electronic components are mechanically and electrically connected on the first surface of said interconnection layer and the second surface of said interconnection layer is connected to a plurality of substrate segments.

16- The multi-chip module of claim 15 wherein each of said substrate segments include a plurality of conductive vias to external solder balls contacts on the second surface of said substrates.

17- A flexible interconnection layer for a semiconductor device having a plurality of relatively rigid substrate segments, said interconnection layer comprising:
a dielectric material having one or more layers of conductors interconnecting said substrates, an array of external contacts under each substrate segment, and a ribbon cable connector integrated into and extending from said interconnection layer.

18- The flexible interconnection layer of claim 17 wherein external contacts include solder balls and a cable connector.
